(19) United States
(12) Patent Application Publication
(10) Pub. No.: US 2010/0138179 A1
(43) Pub. Date: Jun. 3, 2010

(54) DIAGNOSTIC SYSTEM FOR MONITORING INTERNAL CONDITIONS INSIDE A FUEL CELL

(75) Inventors: CHI-YUAN LEE, TAOYUAN COUNTY (TW); SHUO-JEN LEE, TAOYUAN COUNTY (TW); YU-MING LEE, TAOYUAN COUNTY (TW); FANG-BOR WENG, TAOYUAN COUNTY (TW); PEI-HUNG CHI, TAOYUAN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: YUAN ZE UNIVERSITY, TAOYUAN COUNTY 320 (TW)

(21) Appl. No.: 12/431,229

(22) Filed: Apr. 28, 2009

(30) Foreign Application Priority Data
Dec. 3, 2008 (TW) 097146878

(51) Int. Cl. G01R 31/36; G06F 15/00

(52) U.S. Cl. 702/63; 702/183

(57) ABSTRACT

A diagnostic system for monitoring internal conditions inside a fuel cell includes a pair of bipolar plates, a gas diffusion layer, a central controller, and three or more sensors. Each bipolar plate contains a fuel gas channel. The central controller includes a computing unit and a display. Each sensor has a resistor portion, a capacitor portion, a common lead, a resistor line, and a capacitor line for detecting a voltage value, a resistance value, and a capacity value. The display shows out physical information detected by these sensors for diagnosing the fuel cell. The physical information includes voltage, resistance, capacity, temperature, humidity, flow velocity, and flow rate. In which, it can detect various physical information inside the fuel cell. It can monitor the internal conditions continuously and directly. Plus, it can prolong the product life of the fuel cell.

### BACKGROUND OF THE INVENTION

1. Field of the Invention

The present invention relates to a diagnostic system for a fuel cell. Particularly, it relates to a diagnostic system for monitoring internal conditions inside a fuel cell.

2. Description of the Prior Art

The internal conditions (such as temperature, humidity, etc.) of a fuel cell influence the operational efficiency of this fuel cell directly. If the humidity is too high (or too low) or the temperature is too high, its operational efficiency decreases. Therefore, that how to real-time monitor the internal conditions inside a fuel cell becomes an important issue.

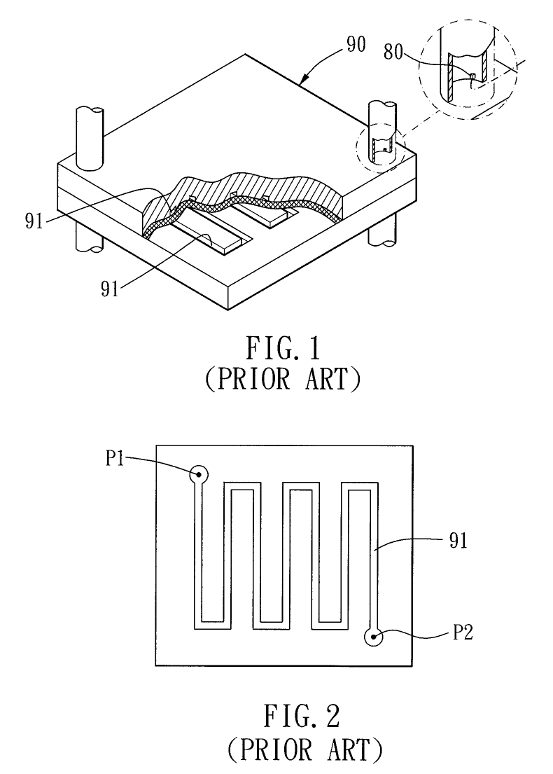

Referring to FIGS. 1 and 2, the conventional detecting method for a fuel cell 90 is to install one sensor 80 at the entrance of the flow channel 91 (see the first position P1 as shown in FIG. 2) and the other sensor 80 at the exit of the flow channel 91 (see the second position P2 as shown in FIG. 2). By doing so, the user can estimate the internal conditions for indirectly monitoring the fuel cell. However, due to the fact that the sensors 80 are disposed only at two ends of the flow channel 91, it is very difficult to precisely detect the internal conditions inside this fuel cell 90. It is almost impossible to know the distribution or the variation of temperature as well as humidity at different points inside this fuel cell 90. Thus, the accuracy of the estimated internal temperature or humidity tends to be very low.

Of course, there is another important factor that will impact the operational efficiency of the fuel cell deeply. That factor is the flow rate in the flow channel 91. In the past, only temperature and humidity are possible to be detected. It cannot detect the flow velocity or the flow rate at a specific point inside the fuel cell 90. That is, not only it cannot detect the temperature and humidity conditions inside the conventional fuel cell 90, but also it is impossible to know the flow velocity and flow speed in the flow channel 91 inside the fuel cell 90. When some problems (such as overheated point occurs or excess water blocks the flow channel 91, etc) happen inside the fuel cell 90, the user cannot quickly react to do some proper adjustment for solving the problems, because the user cannot monitor such variation inside the fuel cell 90. Hence, its overall operational efficiency is poor and it reduces the product life of the fuel cell 90.

### SUMMARY OF THE INVENTION

The objects of the present invention are to provide a diagnostic system for monitoring internal conditions inside a fuel cell. In which, it can detect various physical information inside the fuel cell. It can monitor the internal conditions continuously and directly. Plus, it can prolong the product life of the fuel cell.

In order to achieve the above-mentioned objects, the present invention is provided as a technical solution. This invention is a diagnostic system for monitoring internal conditions inside a fuel cell comprising:

a pair of bipolar plates including a first bipolar plate and a second bipolar plate, a first fuel gas channel being disposed on the first bipolar plate, a second fuel gas channel being disposed on the second bipolar plate;

a gas diffusion layer being disposed between the first fuel gas channel and the second fuel gas channel;

a central controller having a computing unit and a display;

at least three sensors contacting with one of the first fuel gas channel or the second fuel gas channel, each sensor including a resistor portion, a capacitor portion, a common lead, a resistor line, and a capacitor line, so as to detect a voltage value, a resistance value, and a capacity value; the computing unit being able to convert the voltage value into temperature information and to calculate the capacity value into humidity information at a location of the sensor; the computing unit also being able to output flow velocity information based on three adjacent sensors; the common lead, the resistor line, and the capacitor line connecting with the central controller;

the display of the central controller showing out various physical information detected by the sensors so as to diagnose internal conditions inside a fuel cell; the physical information at least including voltage, resistance, capacity, temperature, humidity, flow velocity, and flow rate.

### DETAILED DESCRIPTION OF THE PREFERRED EMBODIMENT

FIG. 1 is a perspective view of a conventional detecting method for a fuel cell.

FIG. 2 is a view showing the conventional detecting points in a fuel cell.

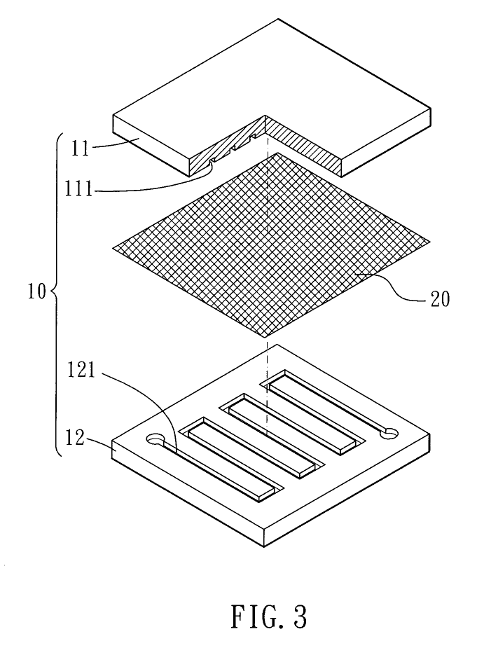

FIG. 3 shows the bipolar plates and the gas diffusion layer of a conventional fuel cell.

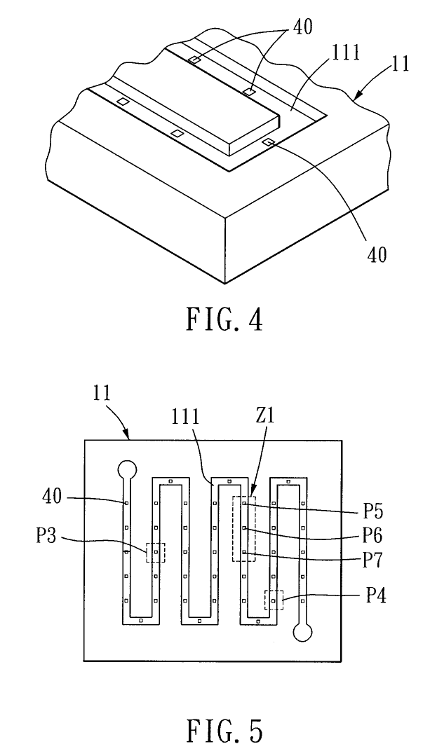

FIG. 4 is a view showing a portion of one preferred embodiment of the present invention

FIG. 5 is a view illustrating the sensors disposed inside the fuel cell.

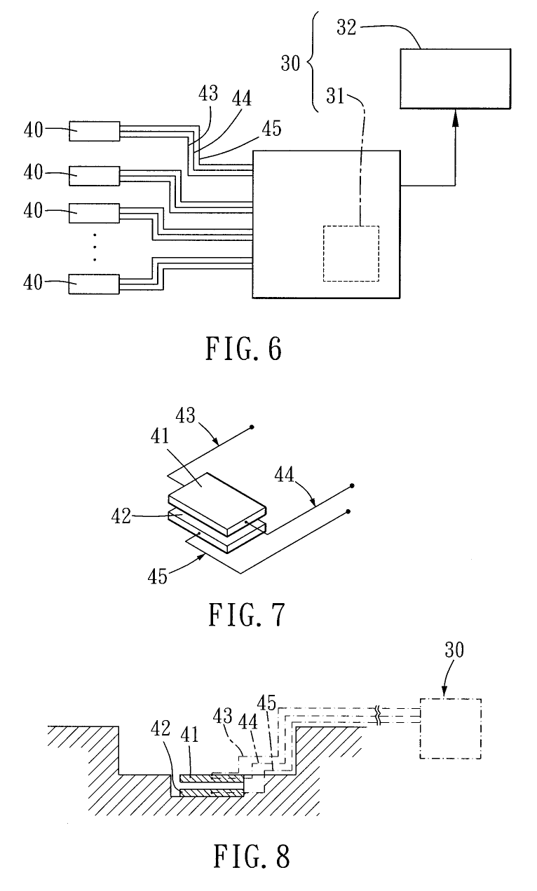

FIG. 6 shows the sensors and the central controller of the present invention.

FIG. 7 is a perspective view showing the detailed structure of the sensor of this invention.

FIG. 8 is a cross-sectional view showing the internal structure of the sensor of this invention.

### DETAILED DESCRIPTION OF THE PREFERRED EMBODIMENT

Referring to FIGS. 3 and 4, the present invention is a diagnostic system for monitoring internal conditions inside a fuel cell. It mainly comprises a pair of bipolar plates 10, a gas diffusion layer 20, a central controller 30, and at least three sensors 40.

About the pair of bipolar plates 10, it includes a first bipolar plate 11 and a second bipolar plate 12. A first fuel gas channel 111 is disposed on the first bipolar plate 11. A second fuel gas channel 121 is disposed on the second bipolar plate 12.

With regard to the gas diffusion layer 20 is disposed between the first fuel gas channel 111 and the second fuel gas channel 121 so as to conduct the electrochemical reaction between two fuel gases (such as hydrogen and oxygen).

Concerning this central controller 30, it has a computing unit 31 and a display 32.

The three or more sensors 40 contacts with one of the first fuel gas channel 111 or the second fuel gas channel 121. Each sensor 40 includes a resistor portion 41, a capacitor portion 42, a common lead 43, a resistor line 44, and a capacitor line 45, so as to detect a voltage value, a resistance value, and a capacity value. The computing unit 41 can convert the voltage value into temperature information and to calculate the capacity value into humidity information at a location of the sensor 40. Also, the computing unit 41 can output flow velocity information based on three adjacent sensors 40. All the common lead 43, the resistor line 44, and the capacitor line 45 of each sensor 40 connect to the central controller 30.

Besides, the display 32 of the central controller 40 shows out various physical information detected by these sensors 40. Based on the physical information, this invention can diagnose internal conditions inside a fuel cell. The physical information at least includes voltage, resistance, capacity, temperature, humidity, flow velocity, and flow rate.

Furthermore, each sensor 40 can detect the voltage, resistance, capacity, temperature, humidity at the location of that sensor 40 (as shown in FIG. 5, one sensor 40 is located at a third position P3; another sensor 40 is located at a fourth position P4; they can detach the voltage, resistance, capacity, temperature and humidity at the third position P3 and the fourth position P4). About utilizing three adjacent sensors 40, they can be combined as a set for detecting the flow velocity. When gas flows through three adjacent sensors 40 (namely the upstream sensor, the middle sensor, and the downstream sensor), the upstream sensor 40 and the downstream sensor 40 can detect two temperature values at the upstream sensor and the downstream sensor. Basically, the middle sensor contains a resistor (not shown). The central controller sends out preset electricity to the middle sensor to heat up the resister of the middle sensor. Since the energy added into the middle sensor will heat up the gas flows by. Theoretically, the temperature detected by the downstream sensor will be higher than the temperature detected by the upstream sensor. Hence, based on the temperature difference (such as a converting table derived from an experimental database), the flow velocity can be known. In addition, the cross-sectional area of the fuel gas channel is known, the corresponding flow rate can be calculated easily.

As illustrated in FIG. 5, it is assumed that there are forty-one sensors 40. Of course, the number can be altered, if needed. In which, three sensors 40 form a flow velocity sensor set Z1. In this flow velocity sensor set Z1, the sensors 40 located at the fifth position P5 and the seventh position P7 are used to detect two voltage values that can be converted into two temperature values. The sensor 40 located at the sixth position P6 is to be used as a heater (adding given energy into the gas flowing by). Based the given energy added and two temperature values (forming a temperature difference), the flow velocity can be calculated.

As shown in FIG. 6, all these sensors 40 connect to the central controller 30. The computing unit 31 can calculate all the information detected by these sensors 40. Then, the display 32 can show out various physical information of the internal conditions inside this fuel cell.

Referring to FIGS. 7 and 8, the sensor 40 contains a resistor portion 41. Two ends of the resistor portion 41 connect with the common lead 43 and the resistor line 44 respectively. The capacity portion 42 of this sensor 40 connects with the capacitor line 45. The resistor portion 41 and the capacity portion 42 are two parallel plates (having a small space) forming a capacitor. When the humidity in the small space (communicated with the first or second fuel gas channel) between the parallel plates changes, the corresponding capacity value changes, too. So, the Therefore, the computing unit 31 can calculate all the information detected by these sensors 40. Finally, the display 32 shows out various physical information of the internal conditions inside this fuel cell. Hence, the diagnostic function can be achieved.

The advantages and functions of this invention can be summarized as follows.

[1] It can detect much information inside the fuel cell. The conventional detecting method only can detect temperature and humidity. But, this invention can detect various physical information inside the fuel cell such as voltage, resistance, capacity, temperature, humidity, flow velocity, and flow rate.

[2] It can monitor the internal conditions continuously and directly. Conventional detecting method is to detect temperature and humidity at the entrance and at the exit of the fuel cell. It is hard to understand the real conditions inside the fuel cell. However, in this invention, there are many sensors disposed at different locations inside the fuel cell. Not only many points can be detected, but also all the internal conditions can be shown on the display immediately and continuously. So, the real-time monitoring function can be achieved.

[3] It can prolong the product life of the fuel cell. In the past, the convention detecting method cannot precise detect the internal conditions inside the fuel cell, so it is hard to make proper adjustment when the fuel cell is in use. Hence, its product life is relative short. But, this invention can monitor all the internal conditions inside the fuel cell and observe the variations at different locations inside the fuel cell. Therefore, proper adjustment can be made immediately during actual operation. The operational efficiency of this fuel cell can be kept at a stable condition. Consequently, it can prolong the product life of the fuel cell.

While this invention has been particularly shown and described with references to the preferred embodiments thereof, it will be understood by those skilled in the art that various changes or modifications can be made therein without departing from the scope of the invention by the appended claims.

What is claimed is:

1. A diagnostic system for monitoring internal conditions inside a fuel cell comprising:
a pair of bipolar plates including a first bipolar plate and a second bipolar plate, a first fuel gas channel being disposed on said first bipolar plate, a second fuel gas channel being disposed on said second bipolar plate;
a gas diffusion layer being disposed between said first fuel gas channel and said second fuel gas channel;
a central controller having a computing unit and a display;
at least three sensors contacting with one of said first fuel gas channel or said second fuel gas channel, each sensor including a resistor portion, a capacitor portion, a common lead, a resistor line, and a capacitor line, so as to detect a voltage value, a resistance value, and a capacity value; said computing unit being able to convert said voltage value into temperature information and to calculate said capacity value into humidity information at a location of said sensor; said computing unit also being able to output a flow velocity information based on three adjacent sensors; said common lead, said resistor line, and said capacitor line connecting with said central controller;
said display of said central controller showing out physical information detected by said sensors so as to diagnose internal conditions inside a fuel cell; said physical information at least including voltage, resistance, capacity, temperature, humidity, flow velocity, and flow rate.

2. The diagnostic system for monitoring internal conditions inside a fuel cell as claimed in claim 1, wherein three sensors form a flow velocity sensor set.
